(19) United States
(12) Patent Application Publication
(10) Pub. No.: US 2010/0151394 A1
(43) Pub. Date: Jun. 17, 2010

(54) System for Contactless Cleaning, Lithographic Apparatus and Device Manufacturing Method

(76) Inventors: Luigi Scaccabarozzi, Valkenswaard (NL); Vadim Yevgenyevich Banine, Deurne (NL); Norbertus Benedictus Koster, Delft (NL); Johannes Hubertus Josephina Moors, Helmond (NL); Maarten Van Kampen, Eindhoven (NL); Ramasamy Raju, Thiruthangal (IN); Wayne Mathew Lytle, Addison, IL (US); David Neil Ruzic, Pesotum, IL (US); Martin John Neumann, Pekin, IL (US)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 12/567,383

(22) Filed: Sep. 25, 2009

Related U.S. Application Data
(60) Provisional application No. 61/100,957, filed on Sep. 29, 2008.

(51) Int. Cl. G03F 7/20; G03B 27/52; B08B 13/00

(52) U.S. Cl. 430/325; 355/30; 156/345.43

(57) ABSTRACT

Embodiments of the invention relate to a system for contactless cleaning of an object surface, a lithographic apparatus including the system, and a method of manufacturing a device. The system may include a He plasma source contained in a chamber and a control unit constructed to modify plasma parameters in use, such as the electron energy distribution of the plasma for causing an increase in formation of He metastables without modifying operational parameters of the plasma source. The control unit may include an electrical biasing unit constructed to apply a positive bias voltage to the object, for attracting free electrons from the plasma. The system may include a supplementary gas source, which may be either pre-mixed with He or be supplied from a further gas source. The supplementary gas may be selected based on a pre-knowledge on a type of particles to be expected on the surface of the object.

### CROSS-REFERENCE TO RELATED APPLICATIONS

The present application claims the benefit under 35 U.S.C §119(e) of U.S. Provisional Patent Application No. 61/100,957, filed Sep. 29, 2008, which is incorporated herein by reference in its entirety.

### BACKGROUND

1. Field

Embodiments of the present invention relate to a system for contactless removing of a particle from a surface of an object, a lithographic apparatus and a method for manufacturing a device using the same.

2. Background

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

In a lithographic apparatus, the size of features that can be imaged onto the substrate is limited by the wavelength of the projection radiation. To produce integrated circuits with a higher density of devices, and hence higher operating speeds, it is desirable to be able to image smaller features. Recently, lithographic apparatus using extreme ultraviolet (EUV) radiation have been provided.

It is an intrinsic feature of an EUV lithographic technology that any contamination deposited on an optical element may cause a substantial detriment of final product quality.

Different cleaning protocols applicable for cleaning optical elements of the lithographic apparatus as well as wafers used therein are currently known. For example, in US 2006/0237667, incorporated herein by reference in its entirety, a cleaning method is described wherein a helium (He) plasma is used for removing contamination from either reticle or wafer, by inducing a charge imbalance between a material of the reticle or wafer and suitable particles conceived to be removed form the surface thereof.

Although the method described in US 2006/0237667 provides a cleaning method wherein the material of the reticle or wafer is substantially not sputtered, it is desirable to provide a cleaning method with increased efficiency and, optionally, with increased selectivity of contamination removal.

### BRIEF SUMMARY

The inventors have discovered a system for contactless removal of a particle from a surface of an object, including a source of plasma constructed to generate He plasma in a direct vicinity of the surface and a control unit constructed to modify plasma parameters to cause an increased generation of He metastables in the He plasma without affecting the source of plasma.

According to another aspect of the invention there is provided a lithographic projection apparatus provided with an optical system including optical elements to condition and/or supply a projection beam of EUV radiation and the system for contactless removal of a particle from a surface of an object, the system including a source of plasma constructed to generate He plasma in a direct vicinity of the surface and a control unit constructed to modify plasma parameters to cause an increased generation of He metastables in the He plasma without affecting the source of plasma.

According to still another aspect of the invention there is provided a device manufacturing method. The method includes providing a beam of EUV radiation using optical elements, projecting the beam onto a target portion of a layer of radiation-sensitive material, and cleaning a surface of at least one optical element using He plasma, wherein a population of He metastables in the He plasma is increased without affecting a source of He plasma.

### BRIEF DESCRIPTION OF THE DRAWINGS/FIGURES

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a side view of an EUV illumination system and projection optics of a lithographic projection apparatus according to FIG. 1;

FIG. 3 depicts a functional scheme of a system for contactless cleaning according to an embodiment of the invention; and

FIG. 4 illustrates a device manufacturing method according to an embodiment of the invention.

### DETAILED DESCRIPTION

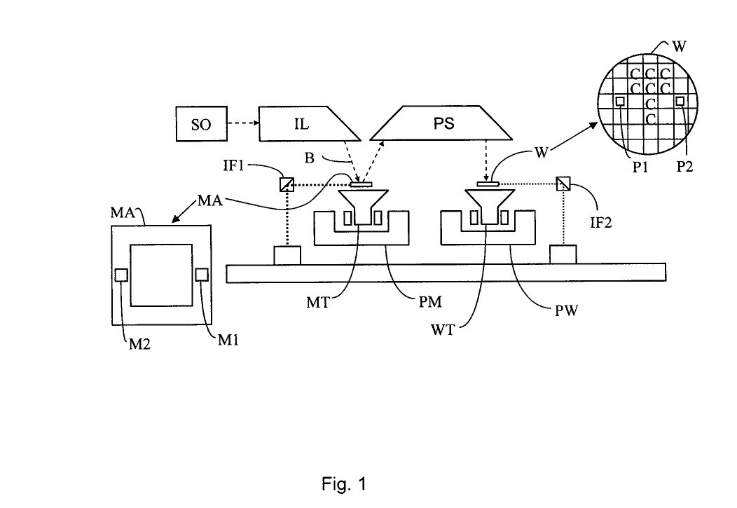

FIG. 1 schematically depicts a lithographic apparatus according to one embodiment of the invention. The apparatus includes:

an illumination system (illuminator) IL configured to condition a radiation beam B (e.g. EUV radiation).

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to radiation beam B by patterning device MA onto a target portion C (e.g. including one or more dies) of substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a reflective type (e.g. employing a reflective mask). Alternatively, the apparatus may be of a transmissive type (e.g. employing a transmissive mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from source SO to illuminator IL with the aid of a beam delivery system BD including, for example, suitable directing mirrors and/or a beam expander. In other cases the source may be an integral part of the lithographic apparatus. Source SO and illuminator IL, together with beam delivery system BD if required, may be referred to as a radiation system.

Illuminator IL may include an adjuster AD for adjusting the angular intensity distribution of the radiation beam. Generally, at least the outer and/or inner radial extent (commonly referred to as σouter and σinner, respectively) of the intensity distribution in a pupil plane of the illuminator can be adjusted. In addition, illuminator IL may include various other components, such as an integrator IN and a condenser CO. The illuminator may be used to condition the radiation beam, to have a desired uniformity and intensity distribution in its cross-section.

Radiation beam B is incident on the patterning device (e.g., mask MA), which is held on the support structure (e.g., mask table MT), and is patterned by the patterning device. Having traversed mask MA, radiation beam B passes through projection system PS, which focuses the beam onto a target portion C of substrate W. With the aid of second positioner PW and position sensor IF2 (e.g. an interferometric device, linear encoder or capacitive sensor), substrate table WT can be moved accurately, e.g. so as to position different target portions C in the path of radiation beam B. Similarly, first positioner PM and another position sensor IF1 can be used to accurately position mask MA with respect to the path of radiation beam B, e.g. after mechanical retrieval from a mask library, or during a scan. In general, movement of mask table MT may be realized with the aid of a longstroke module (coarse positioning) and a shortstroke module (fine positioning), which form part of first positioner PM. Similarly, movement of substrate table WT may be realized using a longstroke module and a shortstroke module, which form part of second positioner PW. In the case of a stepper (as opposed to a scanner), mask table MT may be connected to a shortstroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on mask MA, the mask alignment marks may be located between the dies.

The depicted apparatus could be used in at least one of the following modes:

1. In step mode, mask table MT and substrate table WT are kept essentially stationary, while an entire pattern imparted to the radiation beam is projected onto a target portion C at one time (i.e. a single static exposure). Substrate table WT is then shifted in the X and/or Y direction so that a different target portion C can be exposed. In step mode, the maximum size of the exposure field limits the size of target portion C imaged in a single static exposure.

2. In scan mode, mask table MT and substrate table WT are scanned synchronously while a pattern imparted to the radiation beam is projected onto a target portion C (i.e. a single dynamic exposure). The velocity and direction of substrate table WT relative to mask table MT may be determined by the (de-)magnification and image reversal characteristics of projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, mask table MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

The lithographic apparatus as is set forth in the foregoing advantageously includes a system

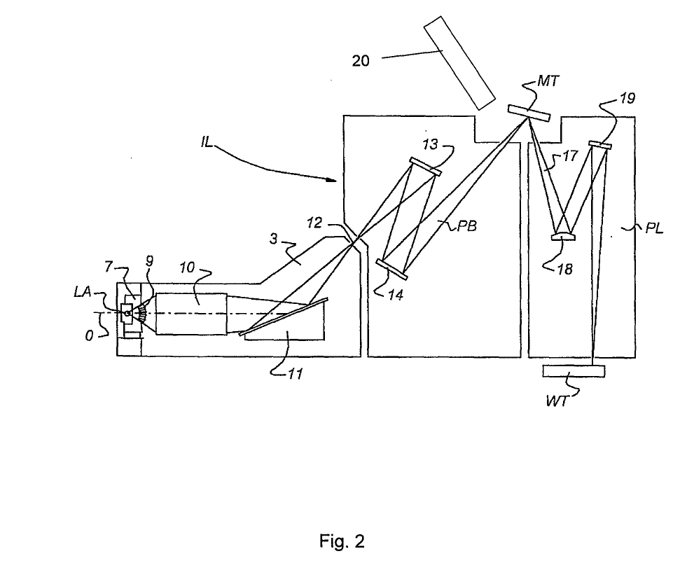

FIG. 2 depicts a side view of an EUV illumination system and projection optics of a lithographic projection apparatus according to FIG. 1, including a radiation system 3 (i.e. “source-collector module”), an illumination system IL, and a projection system PL. The radiation system 3 is provided with a radiation source LA, which may include a discharge plasma source. Radiation source LA may employ a gas or vapor, such as xenon (Xe) gas or lithium (Li) vapor in which very hot plasma can be created by a discharge between electrodes of the radiation source to emit radiation in the EUV range of the electromagnetic spectrum. The very hot plasma is created by causing partially ionized plasma of an electrical discharge to collapse onto an optical axis O. Partial pressure of about 0.1 mbar of Xe, Li vapor or any other suitable gas or vapor may be required for efficient generation of the radiation.

In an embodiment where xenon is used, the plasma may radiate in the EUV range of about 13.5 nm. It will be appreciated that EUV radiation having wavelength of about 6.7 nm is contemplated in another embodiment as well. The radiation emitted by radiation source LA may be led from a source chamber 7 to a contamination barrier 9.

Radiation system 3 (i.e. “source-collector module”) includes a radiation collector 10 which may be formed by, for example, a grazing incidence collector. EUV radiation passed by radiation collector 10 is reflected off a grating spectral purity filter or mirror 11 to be focused in an intermediate focus 12 at an aperture.

A projection beam PB is reflected in illumination system IL via normal incidence reflectors 13, 14 onto a reticle or mask positioned on a reticle or mask table MT. A patterned beam 17 is formed which is imaged in projection optics system PL via reflective elements 18, 19 onto wafer stage or substrate table WT. More elements than shown may generally be present in illumination system IL and projection system PL.

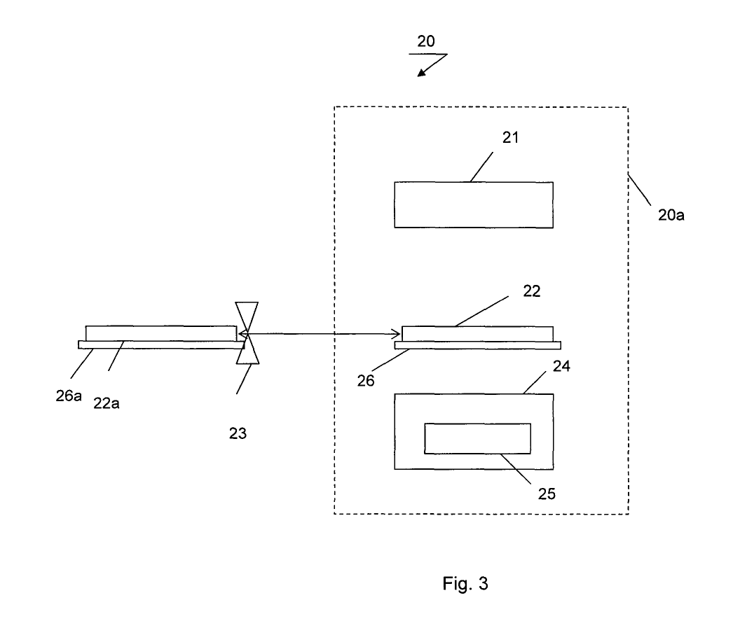

In accordance with an aspect of the invention, the lithographic apparatus includes a system 20 for contactless removal of a particle from a surface of an object 22 (see FIG. 3), for example an optical element, like a mirror or a reticle. The particle may be a silicon nitride (Si₃N₄) particle, a hydrogen (H₂) particle. Alternatively, the particle may be a carbon (C) particle or a carbon compound particle deposited on the surface of the object 22 due to interaction of EUV radiation with CxHy molecules or even left over glue. A person skilled in the art will acknowledge that contamination of the surface of the object 22 more likely contains a combination of the above-mentioned kinds of species rather than of only one kind of species. System 20 may include a source of plasma constructed to generate He plasma in a direct vicinity of the surface and a control unit constructed for modifying plasma parameters for causing an increased generation of He metastables in the He plasma without affecting the source of plasma. System 20 is also suitable for removing contamination particles from a suitable wafer, positioned on wafer table WT. Details of system 20 will be discussed with reference to FIG. 3.

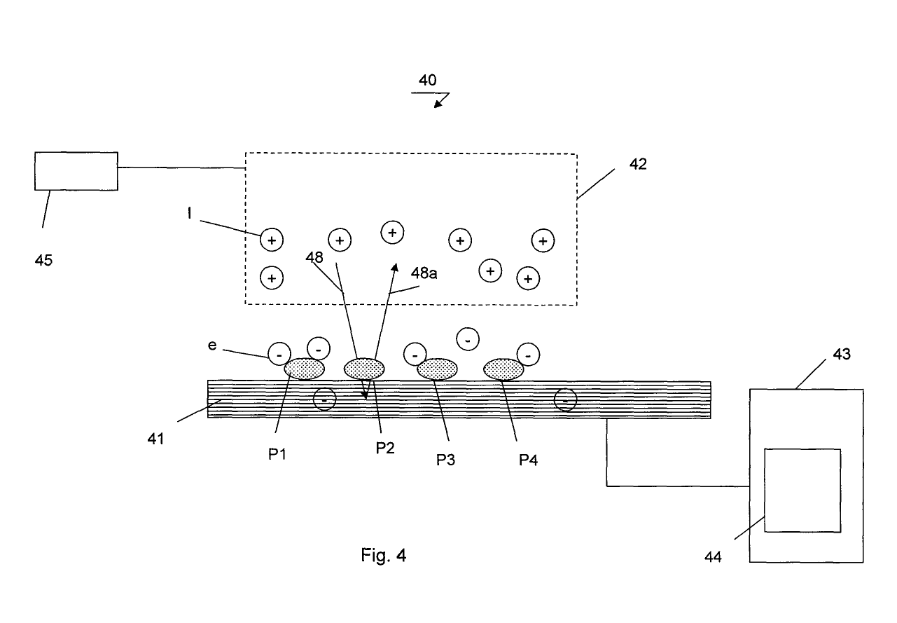

FIG. 3 schematically depicts a functional scheme of a system 20 for contactless cleaning according to an embodiment of the invention. System 20 includes a plasma source 21, contained in a chamber 20a. It will be appreciated that although system 20 is being described as a constituent of a lithographic apparatus, system 20 may be implemented as a stand-alone system. For this purpose system 20 may include a holder 26, which may be translated outside chamber 20a to a position 26a. In order to preserve due vacuum conditions in chamber 20a, the chamber is provided with a valve 23 enabling communication with atmosphere outside chamber 20a for transition of holder 26. In an embodiment, the pressure inside chamber 20a is about 0.5−0.8×10⁻⁷ bar, which has been seen as a favourable pressure range for generating He metastables, at least to create He metastables indicated by transition lines of 388.8 nm and 501.6 nm. When system 20 forms an integral part of a lithographic apparatus, such system is arranged nearby the objects conceived to be cleaned, for example a mirror, a reticle, or a wafer, so that the He plasma is provided in a vicinity of suitable surfaces conceived to be cleaned. It will be appreciated that the term ‘vicinity’ should be interpreted as a minimal distance to the surface of the object 22 allowing for migration of electrons from the plasma to the surface of the object 22 without causing adverse effects to the surface of the object, as will be discussed with reference to FIG. 4.

In accordance with an embodiment of the invention, He is used for forming plasma, which may be supplied from a suitable gas source (not shown). In an embodiment, source 21 is arranged to generate He plasma in a pulsed mode, having a cycle time somewhere between a few seconds and a couple of minutes. System 20 further includes a control unit 24 constructed to modify plasma parameters in use, such as thermal power of the plasma for causing an increase in formation of He metastables without modifying operational parameters of the plasma source.

Control unit 24 may include an electrical biasing unit 25 constructed to apply a positive bias voltage of the object, for attracting free electrons from the plasma. In an embodiment, biasing unit 25 is arranged to apply an electrical bias in the range of 1 to 3 Volt positive on top of the floating potential. The biasing unit may be arranged to operate in a steady-state mode or in a pulsed mode. For the pulsed mode a duty cycle is, in an embodiment, set to at least 50%. In another embodiment, the duty cycle is set to at least 90%. As a result, the electron energy distribution of the plasma, deprived of free electrons, will change thereby substantially increasing formation of He metastables. It is found that in this mode system 20 can be operated with an etch rate of about 20 nm/min. It will be appreciated that the term “floating potential” in the context of the present application relates to an object's potential, relative to the potential of the plasma, wherein the object is immersed in plasma and not electrically connected to the outside world. Usually, the floating potential is negative.

The system 20 may be especially suitable for contactless removal of carbon particles or carbon-containing particles, such as a carbon-containing film.

Additionally, system 20 may include a supplementary gas, which may be either pre-mixed with He, or be supplied from a further gas source (not shown). The supplementary gas may be selected based on a pre-knowledge of a type of particles to be expected on the surface of object 22. For example, when it is known that contamination particles include silicon nitride (Si₃N₄), hydrogen (H₂) may be selected for the supplementary gas, as it forms volatile compounds with silicon (Si) and nitrogen (N), thereby efficiently removing Si₃N₄ from the surface. It will be appreciated that selection of a suitable supplementary gas for a known contamination falls within an ordinary skill of the artisan.

FIG. 4 illustrates a device manufacturing method according to an embodiment of the invention. In accordance with a method of manufacturing a device according to an embodiment of the invention, a suitable object, for example an optical element, like a reticle or a mirror, or a wafer may be subjected to plasma cleaning as described in the foregoing. For example, for the object a multi-layer mirror 41 in system 40 may be selected. Multi-layer mirrors are used in a lithographic apparatus, for example in an EUV lithographic apparatus, for conditioning and/or for projecting a beam of radiation. For example, an incoming beam 48 may be reflected by the multi-layer mirror 41, after which it will be propagating in a direction 48a. When a surface of mirror 41 is contaminated with particles P1, P2, P3, P4, which may correspond to the same or different chemical species, an intensity of the reflected beam 48a may be reduced, for example when the lithographic apparatus is operable using EUV radiation in the range of 6.7-13.5 nm. It will be understood that, next to absorption, other effects may take place deteriorating quality of the beam 48a. For example, quality of the patterning of the incoming beam may be deteriorated when particle contamination is present on a reticle.

In accordance with an embodiment of the invention, the device manufacturing method includes the step of cleaning a surface of at least one optical element using He plasma 42, wherein population of He metastables in the He plasma is increased without affecting a source 45 of He plasma. For this reason, He plasma, suitably generated by plasma source 45 is provided in a vicinity of object 41, which is electrically biased by a biasing unit 44 forming part of a control unit 43, to a value in the range of +1 to +3 Volts above the floating potential. As a result, electrons “e” are attracted to the surface of object 41 and are conducted away from the object. By allowing the biasing unit to apply the bias voltage in a pulsed way, for example with a duty cycle of at least 50%, and in another example with a duty cycle of at least 90%, still more electrons are swept away from plasma 42, leaving positive ions “I” behind. This leads to a change in the electron energy distribution in the plasma, as more electrons need to be created to maintain a steady state density in plasma 42, which, in turn, leads to a substantial increase in excitations and increased formation of He metastables in plasma 42.

In accordance with an embodiment of the method of the invention, helium, used for production of plasma 42, is supplemented with a further gas, which is purposefully selected for forming volatile compounds with particles P1, P2, P3 or P4. For example, for removing Si₃N₄ hydrogen may be used, as it undergoes chemical reaction with Si₃N₄ and forms volatile compounds with Si and N. It will be appreciated that it is also possible to use a supplementary gas, as described above, as a supplementary measure for He plasma cleaning, without actively modifying plasma parameters as described herein above.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein, where the context allows, encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 6.7-13.5 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

What is claimed is:

1. A system for contactless removal of a particle from a surface of an object, comprising:
a source of plasma constructed to generate He plasma in a vicinity of the surface; and
a control unit constructed to modify plasma parameters to cause an increased generation of He metastables in the He plasma without affecting the source of plasma.

2. A system according to claim 1, wherein the control unit is constructed to alter the electron energy distribution of the plasma.

3. A system according to claim 2, wherein the control unit comprises an electrical biasing unit constructed to apply an electrically positive bias to the object in a pulsed mode.

4. A system according to claim 3, wherein a duty cycle of the pulsed mode is at least 50%.

5. A system according to claim 3, wherein a duty cycle of the pulsed mode is at least 90%.

6. A system according to claim 3, wherein the electrically positive bias is in the range of 1 to 3 Volt above floating potential.

7. A system according to claim 4, wherein the electrically positive bias is in the range of 1 to 3 Volt above floating potential.

8. A system according to claim 5, wherein the electrically positive bias is in the range of 1 to 3 Volt above floating potential.

9. A system according to claim 2, wherein the control unit comprises an electrical biasing unit constructed to apply an electrically positive bias to the object in a steady-state mode.

10. A system according to claim 1, further comprising a supplementary gas conceived to undergo a chemical reaction with the particle so as to remove the particle from the surface.

11. A system according to claim 10, wherein the supplementary gas comprises molecular hydrogen, atomic hydrogen, or a combination thereof.

12. A lithographic projection apparatus comprising:
an optical system comprising optical elements configured to condition or supply a projection beam of EUV radiation; and
a system according to claim 1, constructed to clean a surface of one or more of said optical elements.

13. A device manufacturing method, comprising:
providing a beam of EUV radiation using optical elements;
projecting the beam onto a target portion of a layer of radiation-sensitive material; and
cleaning a surface of at least one optical element using He plasma, wherein a population of He metastables in the He plasma is increased without affecting a source of He plasma.

14. A device manufacturing method according to claim 13, further comprising the step of providing a supplementary gas conceived to undergo a chemical reaction with the particle for removing the particle from the surface.
